(19) United States
(12) Patent Application Publication
(10) Pub. No.: US 2024/0104263 A1
(43) Pub. Date: Mar. 28, 2024

(54) ALGORITHM SELECTING METHOD AND INFORMATION PROCESSING APPARATUS

(71) Applicant: Fujitsu Limited, Kawasaki-shi (JP)

(72) Inventor: Satoshi IMAMURA, Kawasaki (JP)

(73) Assignee: Fujitsu Limited, Kawasaki-shi (JP)

(21) Appl. No.: 18/337,474

(22) Filed: Jun. 20, 2023

(30) Foreign Application Priority Data
Sep. 27, 2022 (JP) 2022-153762

(51) Int. Cl. G06F 30/20

(52) U.S. Cl. CPC G06F 30/20

(57) ABSTRACT

An information processing apparatus calculates a plurality of first molecular energies corresponding to a plurality of first interatomic distances by using a first algorithm that iteratively updates a solution until a convergence condition is satisfied. The information processing apparatus specifies, based on a slope of a line segment indicating a relationship between the plurality of first interatomic distances and iteration counts, a plurality of second interatomic distances for which molecular energy is to be calculated by using a second algorithm. The information processing apparatus calculates second molecular energies corresponding to the specified plurality of second interatomic distances by using the second algorithm.

### CROSS-REFERENCE TO RELATED APPLICATION

This application is based upon and claims the benefit of priority of the prior Japanese Patent Application No. 2022-153762, filed on Sep. 27, 2022, the entire contents of which are incorporated herein by reference.

### FIELD

The embodiments discussed herein relate to an algorithm selecting method and an information processing apparatus.

### BACKGROUND

Computers perform molecular simulations in which the properties of molecules are analyzed through numerical calculation. Molecular simulations are used in industrial fields, such as the development of materials or pharmaceuticals. Molecular simulations include quantum chemical calculations that microscopically calculate the energy of a molecule based on the electronic state of the molecule and the Schrödinger equation.

Algorithms for quantum chemical calculations include full configuration interaction (FCI), coupled-cluster singles and doubles (and triples) (CCSD(T)), and variational quantum eigensolver (VQE). Some algorithms iteratively calculate the energy of a molecule while changing the electron configuration, and search for the electron configuration that minimizes the energy for a given molecular structure. In this case, the algorithm outputs the smallest energy value as the “ground-state energy”.

Note that for configuration interaction, there is a proposed quantum chemical calculator apparatus that dynamically selects some molecular orbitals out of the plurality of molecular orbitals of a given molecule and calculates molecular energy based on electron configurations that are limited to the selected molecular orbitals.

See, for example, International Publication Pamphlet No. WO2022/097298.

### SUMMARY

According to an aspect, there is provided a non-transitory computer-readable recording medium storing therein a computer program that causes a computer to execute a process including: calculating each of a plurality of first molecular energies corresponding to a plurality of first interatomic distances by using a first algorithm that iteratively updates a solution until a convergence condition is satisfied; specifying, based on a slope of a line segment indicating a relationship between the plurality of first interatomic distances and iteration counts of the first algorithm until the convergence condition is satisfied, a plurality of second interatomic distances; and calculating a plurality of second molecular energies corresponding to the plurality of second interatomic distances by using a second algorithm which differs from the first algorithm.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 depicts an information processing apparatus according to a first embodiment;

FIG. 2 depicts example hardware of an information processing apparatus according to a second embodiment;

FIG. 3 depicts an example comparison of algorithms in terms of accuracy and execution time;

FIG. 4 depicts example potential energy curves;

FIG. 5 is a graph depicting an example relationship between distance and iteration count;

FIG. 6 is a graph depicting an example relationship between distance, error, and slope;

FIG. 7 is a block diagram depicting example functions of the information processing apparatus;

FIG. 8 is a diagram depicting an example structure of control data;

FIG. 9 is a flowchart depicting an example procedure of a quantum chemical calculation;

FIG. 10 is a flowchart depicting an example procedure for algorithm switching;

FIG. 11 depicts an example of piecewise linear regression analysis; and

FIG. 12 depicts another example of piecewise linear regression analysis.

### DESCRIPTION OF EMBODIMENTS

It is possible for computers to generate energy curve information, which indicates the relationship between interatomic distance and energy, by calculating molecular energy while changing the distance between two atoms placed in focus. However, algorithms for quantum chemical calculation have a trade-off between accuracy and execution time. This means that from the viewpoint of the efficiency of a quantum chemical calculation, the method used to select an algorithm for a plurality of interatomic distances is important.

Several embodiments will be described below with reference to the accompanying drawings.

### First Embodiment

A first embodiment will now be described.

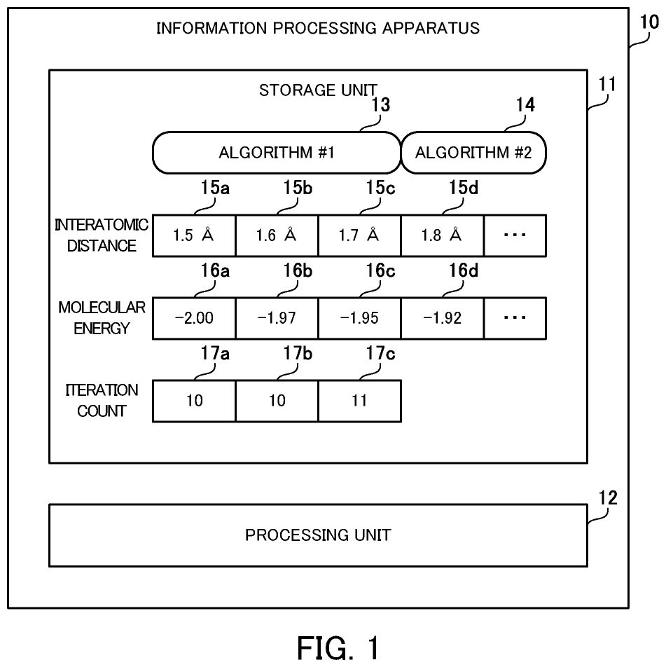

FIG. 1 depicts an information processing apparatus according to the first embodiment.

The information processing apparatus 10 according to the first embodiment performs a quantum chemical calculation, which is a type of molecular simulation. The information processing apparatus 10 generates energy curve information indicating the relationship between interatomic distance and molecular energy. This energy curve information may also be referred to as a potential energy curve (PEC). The information processing apparatus 10 may be a client apparatus or may be a server apparatus. The information processing apparatus 10 may be referred to as a “computer”, a “molecular simulation apparatus”, a “quantum chemical calculation apparatus”, or an “algorithm selection apparatus”.

The information processing apparatus 10 includes a storage unit 11 and a processing unit 12. The storage unit 11 may be a volatile semiconductor memory, such as a random access memory (RAM), or may be non-volatile storage, such as a hard disk drive (HDD) or flash memory. As examples, the processing unit 12 is a processor such as a central processing unit (CPU), a graphics processing unit (GPU), or a digital signal processor (DSP). However, the processing unit 12 may include an electronic circuit, such as an application specific integrated circuit (ASIC) and/or a field programmable gate array (FPGA). The processor executes a program stored in a memory such as RAM (which may be the storage unit 11), for example. A group of processors may be referred to as a “multiprocessor” or simply as a “processor”.

The storage unit 11 stores a plurality of different interatomic distances, including interatomic distances 15a, 15b, 15c, and 15d. The interatomic distances 15a, 15b, 15c, and 15d are distances between two specific atoms contained in a molecule, and are interatomic distances at which molecular energy is to be calculated. The interatomic distance 15b is greater than the interatomic distance 15a, the interatomic distance 15c is greater than the interatomic distance 15b, and the interatomic distance 15d is greater than the interatomic distance 15c.

The storage unit 11 also stores a plurality of molecular energies including molecular energies 16a, 16b, 16c, and 16d. The molecular energies 16a, 16b, 16c, and 16d correspond to the interatomic distances 15a, 15b, 15c, and 15d, and are calculated by the processing unit 12 using methods described later. The molecular energies 16a, 16b, 16c, and 16d are ground-state energies as the minimum energies of a molecule at the designated interatomic distances.

The molecular energies 16a, 16b, and 16c are calculated using an algorithm 13. The molecular energy 16d is calculated using the algorithm 13 or an algorithm 14. The algorithm 13 iteratively updates the molecular energy until a convergence condition is satisfied. As one example, the algorithm 13 iteratively calculates the molecular energy while changing the electronic configuration, and searches for the electronic configuration that minimizes the molecular energy. As one example, the convergence condition is that the difference between the most recently calculated molecular energy and the molecular energy in the immediately previous iteration falls below a threshold.

As examples, the algorithm 13 is CCSD (Coupled Cluster Singles and Doubles) or CCSD(T). The algorithm 14 differs from the algorithm 13. The algorithm 14 preferably has a longer execution time and a higher solution accuracy than the algorithm 13. As one example, the algorithm 14 is VQE. Note that the information processing apparatus 10 may have another information processing apparatus execute one or both of the algorithms 13 and 14. The algorithm 14 may be executed by a von Neumann-type classical computer or by a gate-type quantum computer.

The algorithm 13 may be an approximation algorithm that ignores the effects of higher-order electronic excitations. When this is the case, the solution of the algorithm 13 may be relatively accurate so long as the interatomic distance is small. On the other hand, when the interatomic distance is large, the accuracy of the solution of the algorithm 13 may be low due to the large influence of outer molecular orbitals on molecular energy. Also, with the algorithm 13, there may be negative correlation between the accuracy of the solution and the iteration count, and the iteration count may increase as the accuracy of the solution decreases. This is because when the accuracy of a solution is low, further increases in the iteration count may simply result in the solution continuously fluctuating in the vicinity of the correct value without converging.

The storage unit 11 also stores a plurality of iteration counts including iteration counts 17a, 17b, and 17c. The iteration counts 17a, 17b, and 17c are iteration counts of the algorithm 13 until the convergence condition is satisfied, and correspond to the interatomic distances 15a, 15b, and 15c. The iteration counts 17a, 17b, and 17c are measured when calculating the molecular energies 16a, 16b, and 16c.

The processing unit 12 uses the algorithm 13 to calculate each of a plurality of first molecular energies, which include the molecular energies 16a, 16b, and 16c, corresponding to a plurality of first interatomic distances, which include the interatomic distances 15a, 15b, and 15c. As one example, the processing unit 12 preferentially calculates the molecular energy starting from the smallest out of a set of interatomic distances for which calculation is to be performed. When doing so, the processing unit 12 measures a plurality of iteration counts including the iteration counts 17a, 17b, and 17c corresponding to the plurality of first interatomic distances including the interatomic distances 15a, 15b and 15c.

The processing unit 12 determines whether the slope of a line segment indicating the relationship between the plurality of first interatomic distances and the plurality of iteration counts exceeds a threshold. As one example, the slope of this line segment is the ratio of the change in the iteration count to the increase in the interatomic distance when a plurality of iteration counts have been aligned in ascending order of the interatomic distance. The processing unit 12 may calculate a line segment from a plurality of first interatomic distances and a plurality of iteration counts by a least squares method. When calculating the molecular energy in ascending order of interatomic distances, the processing unit 12 may calculate the slope from a certain number (for example, five) of the most recent interatomic distances, or may calculate the slope from every interatomic distance.

As one example, the threshold is the slope calculated immediately before the most recent interatomic distance, out of the plurality of first interatomic distances. The processing unit 12 may determine whether the slope has exceeded the threshold a certain number of times (for example, three times) in succession. As one example, while calculating the molecular energy in ascending order of the interatomic distances, the processing unit 12 determines whether the slope at the most recent interatomic distance has been greater than the slope at the previous interatomic distance for a certain number of times in succession.

As one example, the threshold is the slope of a line segment for the smaller interatomic distance out of the slopes of two line segments calculated from the iteration counts of all the interatomic distances. The processing unit 12 may calculate two line segments from all of the interatomic distances and all of the iteration counts through piecewise regression analysis or the like. As one example, the processing unit 12 determines whether the slope of a line segment in a section where the interatomic distance is large is greater than the slope of a line segment in a section where the interatomic distance is small. In this case, interatomic distances belonging to the section where the interatomic distance is large are “second interatomic distances”.

When the slope of the line segment does not exceed the threshold, the processing unit 12 uses the algorithm 13 to calculate second molecular energies corresponding to second interatomic distances that are greater than any of the interatomic distances 15a, 15b, and 15c. In this example the interatomic distance 15d corresponds to a “second interatomic distance”, and the molecular energy 16d corresponds to a “second molecular energy”. As one example, the interatomic distance 15d is one larger than the interatomic distance 15c (the next larger interatomic distances after the interatomic distances 15c) in the set of interatomic distances subjected to calculation. After the molecular energy 16d has been calculated, the processing unit 12 may calculate the slope of a new line segment and compare this slope with the threshold.

On the other hand, when the slope of the line segment exceeds the threshold, the processing unit 12 uses the algorithm 14 to calculate the molecular energy 16d. In this case, the processing unit 12 may also use the algorithm 14 to calculate the remaining molecular energies corresponding to the remaining interatomic distances which are larger than the interatomic distance 15d, out of the set of interatomic distances subjected to calculation.

The processing unit 12 outputs energy curve information indicating the relationship between the interatomic distances and the calculated molecular energies. The processing unit 12 may store this energy curve information in non-volatile storage, display the energy curve information on a display device, and/or transmit the energy curve information to another information processing apparatus.

As described above, the information processing apparatus 10 according to the first embodiment uses the algorithm 13 to individually calculate the plurality of first molecular energies corresponding to the plurality of first interatomic distances. When the slope of a line segment indicating the relationship between the plurality of first interatomic distances and the iteration counts of the algorithm 13 does not exceed a threshold, the information processing apparatus 10 uses the algorithm 13 to calculate second molecular energies corresponding to second interatomic distances that are larger than any of the first interatomic distances. On the other hand, when the slope exceeds the threshold, the information processing apparatus 10 calculates the second molecular energies using the algorithm 14 that differs from the algorithm 13.

By doing so, the algorithm is appropriately switched according to the interatomic distance, resulting in energy curve information being generated using a quantum chemical calculation with higher accuracy and at a higher speed. As one example, the overall execution time is reduced compared to a case where molecular energy is calculated for every interatomic distance using a highly accurate algorithm. In addition, the accuracy of the molecular energies is improved compared to a case where molecular energy is calculated for every interatomic distance using an algorithm with a short execution time. Also, with the algorithm 13, the greater the interatomic distance, the more likely the accuracy is to fall, and the iteration count tends to increase when the accuracy starts to decrease significantly. For this reason, there is a switch from the algorithm 13 to the algorithm 14 as the accuracy decreases, which achieves a favorable balance between the accuracy of the molecular energies and the execution time.

Note that when the slope exceeds the threshold, the information processing apparatus 10 may also use the algorithm 14 to calculate the remaining molecular energies corresponding to the remaining interatomic distances that are larger than the second interatomic distance. By doing so, the accuracy of the molecular energy is improved throughout the energy curve information. Also, the threshold to be compared with the slope of the most recent line segment may be the slope at the immediately previous first interatomic distance or may be the slope of a line segment for a smaller interatomic distance out of the slopes of two line segments. By doing so, the information processing apparatus 10 is capable of appropriately detecting a fall in accuracy of the molecular energy calculated by the algorithm 13.

The algorithm 14 may be an algorithm with a longer execution time than the execution time of the algorithm 13 and whose solution has higher accuracy than the algorithm 13. As examples, the algorithm 13 may be CCSD(T) and the algorithm 14 may be VQE. With this configuration, the information processing apparatus 10 uses the algorithm 14 to cover interatomic distances for which the accuracy of the algorithm 13 is insufficient, thereby achieving a favorable balance between accuracy and execution time.

The information processing apparatus 10 may determine whether a third algorithm is usable based on the molecular information and the available memory capacity, and use the algorithm 13 when the third algorithm is not usable. By doing so, it is possible to consider yet another algorithm from the viewpoint of memory usage and select a more appropriate algorithm. The information processing apparatus 10 may estimate the memory usage from at least one of the number of electrons and the number of molecular orbitals of the target molecule, and determine that the third algorithm is not usable when the estimated memory usage exceeds the available memory capacity. By doing so, it is possible to appropriately determine whether the third algorithm is usable.

The third algorithm may be an algorithm with a longer execution time than the algorithm 14 and a higher solution accuracy than the algorithm 14. As one example, the third algorithm may be FCI. By doing so, the accuracy of the molecular energy is improved throughout the energy curve information for small molecules for which calculation uses less memory.

### Second Embodiment

Next, a second embodiment will be described.

An information processing apparatus 100 according to the second embodiment generates, through quantum chemical calculation, a potential energy curve indicating the relationship between the distance between two atoms in focus and the ground-state energy of a molecule. The information processing apparatus 100 may execute a plurality of algorithms used for quantum chemical calculations. However, some or all of such algorithms may be executed by other information processing apparatuses. Such other information processing apparatuses may include a quantum computer.

The information processing apparatus 100 may be a client apparatus or a server apparatus. Also, the information processing apparatus 100 may be installed in a data center or included in a cloud system. This cloud system may receive a job request for a quantum chemical calculation via a network and send a generated potential energy curve in reply. The information processing apparatus 100 may be referred to as a “computer”, a “molecular simulation apparatus”, or a “quantum chemical calculation apparatus”. The information processing apparatus 100 corresponds to the information processing apparatus 10 according to the first embodiment.

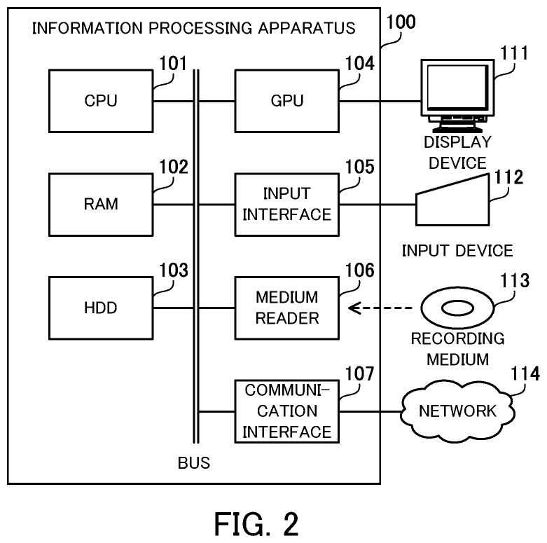

FIG. 2 depicts example hardware of an information processing apparatus according to the second embodiment.

The information processing apparatus 100 includes a CPU 101, RAM 102, an HDD 103, a GPU 104, an input interface 105, a medium reader 106, and a communication interface 107 that are connected to a bus. The CPU 101 corresponds to the processing unit 12 in the first embodiment. The RAM 102 or the HDD 103 corresponds to the storage unit 11 in the first embodiment.

The CPU 101 is a processor that executes instructions of a program. The CPU 101 loads a program and data stored in the HDD 103 into the RAM 102 and executes the program. The information processing apparatus 100 may include a plurality of processors.

The RAM 102 is a volatile semiconductor memory that temporarily stores a program to be executed by the CPU 101 and data used in computation by the CPU 101. The information processing apparatus 100 may have a type of volatile memory aside from RAM.

The HDD 103 is nonvolatile storage that stores software programs, such as an operating system (OS), middleware, and application software, as well as data. The information processing apparatus 100 may include other types of non-volatile storage, such as flash memory and/or a solid state drive (SSD).

The GPU 104 performs image processing in cooperation with the CPU 101 and outputs images to a display apparatus 111 connected to the information processing apparatus 100. As examples, the display apparatus 111 is a cathode ray tube (CRT) display, a liquid crystal display, an organic electro luminescence (EL) display, or a projector. Another type of output device, such as a printer, may be connected to the information processing apparatus 100. The GPU 104 may also be used as a general purpose computing on graphics processing unit (GPGPU). The GPU 104 may execute a program according to instructions from the CPU 101. The information processing apparatus 100 may include a volatile semiconductor memory aside from the RAM 102 as GPU memory.

The input interface 105 receives an input signal from an input device 112 connected to the information processing apparatus 100. As examples, the input device 112 is a mouse, touch panel, or keyboard. A plurality of input devices may be connected to the information processing apparatus 100.

The medium reader 106 is a reader apparatus that reads programs and data recorded on a recording medium 113. As examples, the recording medium 113 is a magnetic disk, an optical disc, or a semiconductor memory. Magnetic disks include flexible disks (FD) and HDD. Optical discs include compact discs (CD) and digital versatile discs (DVD). The medium reader 106 copies the program and data read from the recording medium 113 into another recording medium, such as the RAM 102 or the HDD 103. The read program may be executed by the CPU 101.

The recording medium 113 may be a portable recording medium. The recording medium 113 may be used to distribute programs and data. The recording medium 113 and the HDD 103 may also be referred to as “computer-readable recording media”.

The communication interface 107 communicates with other information processing apparatuses via the network 114. The communication interface 107 may be a wired communication interface connected to a wired communication apparatus, such as a switch or a router, or may be a wireless communication interface connected to a wireless communication apparatus, such as a base station or an access point.

Next, a quantum chemical calculation and solution-finding algorithms will be described.

A quantum chemical calculation is one type of molecular simulation and analyzes molecular structures and intermolecular interactions from electron states. Quantum chemical calculations are sometimes used to support development of materials and pharmaceuticals. A quantum chemical calculation is a microscopic molecular simulation that has high analytical accuracy but also has a high computational load.

A quantum chemical calculation solves the Schrödinger equation HΨ=EΨ. Here, H is the Hamiltonian operator, Ψ is the wave function, and E is the energy. The Hamiltonian operator H depends on the molecular structure subjected to calculation. The wave function Ψ corresponds to the eigenstate of electrons, and the energy E corresponds to the eigenenergy corresponding to Ψ. The quantum chemical calculation calculates the ground-state energy when the molecular structure is stable. However, it is difficult to directly solve the Schrödinger equation.

For this reason, in a quantum chemical calculation, the wave function Ψ is represented by a ground-state function. The ground-state function is a linear combination of known functions. Each of the plurality of terms included in the ground-state function corresponds to a molecular orbital. A molecular orbital is a location where any one of the electrons contained in a molecule may enter. The quantum chemical calculation receives molecular information indicating the positions of multiple atoms contained in a molecule, a solution-finding algorithm, and a ground-state function that have been designated by the user, and calculates the ground-state energy based on the designated information. However, in this second embodiment, the solution-finding algorithm may be left undesignated.

The information processing apparatus 100 generates a potential energy curve by using a quantum chemical calculation. The potential energy curve indicates potential energies corresponding to different interatomic distances. The potential energy is the energy that a molecule would have when each atom is assumed to be at rest. The horizontal axis of the potential energy curve represents the distance between two specified atoms. The vertical axis of the potential energy curve represents the ground-state energy.

The unit of distance is angstroms (Å), for example. The unit of energy is hartrees, for example. Energy is calculated for each of a plurality of discrete distances included in a certain range. This plurality of distances may be equally spaced. As one example, energy is calculated from 0.6 Å to 2.6 Å at 0.1 Å intervals. The potential energy curve is generated by plotting the calculated energies and connecting the plotted points with a line. A minimum on the potential energy curve may represent the most stable state of the molecule. A maximum on the potential energy curve may represent a transition state of the molecule.

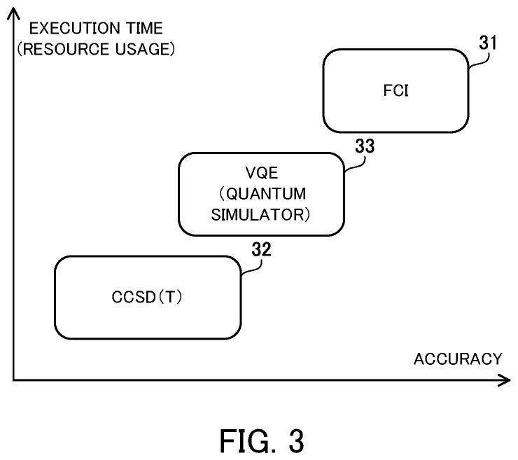

FIG. 3 depicts an example comparison of algorithms in terms of accuracy and execution time.

In this second embodiment, algorithms 31, 32, and 33 are used for the quantum chemical calculation. The algorithm 31 is FCI. The algorithm 32 is CCSD(T). However, CCSD may be used instead of CCSD(T). The algorithm 33 is VQE. VQE may be executed by a gate-based quantum computer, or by a classical computer that simulates the operation of a quantum computer by using software. In this second embodiment, the information processing apparatus 100 executes VQE using a quantum simulator implemented on a classical computer.

FCI is a classical algorithm intended for execution on a classical computer. FCI finds an exact solution for energy based on molecular information and a ground-state function that have been designated. For this reason, FCI produces a highly accurate solution but has a long execution time. FCI has a computational load of an order given by the factorial of the number of molecular orbitals. This makes it difficult to calculate the energy of large-scale molecules using FCI. Due to FCI's nature in obtaining an exact solution, energy values calculated by FCI may be interpreted as correct.

Note that the expression “classical computer” here refers to a von Neumann computer for example, as opposed to a “quantum computer”. The expression “classical algorithm” is an algorithm that does not use a quantum circuit, in contrast to the “quantum algorithm” described later. A molecule to be simulated is sometimes referred to as a “system”. Execution time is positively correlated with resource usage, and may be proportional to resource usage. The hardware resources used by a quantum chemical calculation may include processing time of a processor and storage regions of a memory.

CCSD(T) is a classical algorithm intended for execution on a classical computer. CCSD(T) finds an approximate solution for energy based on molecular information and a ground-state function that have been designated. For this reason, compared to FCI, CCSD(T) has lower solution accuracy but a shorter execution time. CCSD(T) has a computational load of an order that is the seventh power of the number of molecular orbitals. Note that CCSD has lower solution accuracy and shorter execution time than CCSD(T).

CCSD(T) calculates, as electron states, the effect of single-electron excitation and double-electron excitation on energy precisely, and finds the effect on energy of triple-electron excitation from perturbations. CCSD(T) ignores the effects of higher-order electron excitations of four or more electrons. CCSD(T) iteratively calculates energy while changing the electron configuration and searches for the minimum energy. CCSD(T) performs iterative calculations until the calculated energy converges. As one example, CCSD(T) compares the most recently calculated energy with the energy calculated in the immediately previous iteration, and stops the iterative calculation when the difference between the two is less than a threshold.

CCSD(T) often calculates a relatively favorable approximation to FCI when the interatomic distance is small. On the other hand, there are cases where CCSD(T) calculates an approximate solution with low accuracy when the interatomic distance is large. When the interatomic distance is large, the effect of outer molecular orbitals on the energy is also large, which increases the error in the approximate solution produced by CCSD(T) that ignores the effects of higher-order electron excitation of four or more electrons. Also, with CCSD(T), when the accuracy of the energy that is finally outputted is low, there is a tendency for the iteration count until convergence to increase. This is because even when iterative calculation is performed, the approximate solution continues to fluctuate in the vicinity of the correct value, and the approximate solution does not stably converge toward the correct solution.

VQE is a quantum algorithm intended for execution on a gate-type quantum computer. VQE may be executed using a noisy intermediate-scale quantum (NISQ) computer. However, as mentioned earlier, it is also possible to run VQE on a classical computer using a quantum simulator. In this case, each additional qubit doubles the memory usage and computational load of a classical computer. The solution accuracy and execution time of VQE are both between FCI and CCSD(T). That is, the accuracy of the solution is lower than FCI but higher than CCSD(T). The execution time is shorter than FCI but longer than CCSD(T).

VQE forms a quantum circuit that uses a plurality of qubits to generate quantum states based on a designated ground-state function. This quantum circuit is sometimes referred to as an “ansatz circuit”. VQE also forms a quantum circuit that measures energy from quantum states based on a Hamiltonian operator corresponding to designated molecular information. This quantum circuit is sometimes referred to as a “measurement circuit”. A quantum circuit is a quantum computational model described as a combination of quantum gates. Quantum computers implement quantum circuits using physical qubits. In a quantum simulator, pseudo-qubit data is stored in a memory and pseudo-quantum gate operations are implemented using a classical program.

VQE uses an ansatz circuit to generate quantum states and uses a measurement circuit to measure energy. Individual measurements are affected by noise and fluctuations. VQE performs the generation of quantum states and measurement of energy a plurality of times for the same electron configuration and calculates average values as expected values of energy. VQE changes the parameter values for generating quantum states so that the expected value of energy becomes smaller. Changing the parameter values corresponds to changing the electron configuration. VQE searches for the ground-state energy by repeating the above processing. As one example, VQE repeats the above processing until the expected value of energy converges.

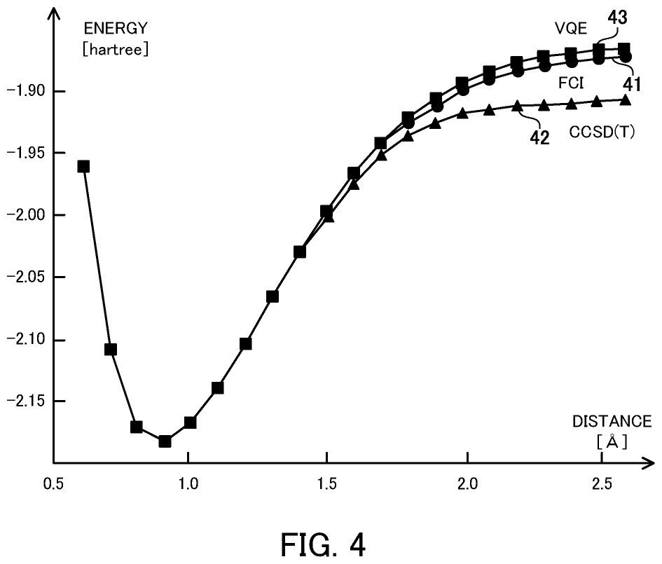

FIG. 4 depicts example potential energy curves.

The curve 41 depicts the energy calculated by FCI. Here, the curve 41 is interpreted as the correct potential energy curve. The curve 42 depicts the energy calculated by CCSD(T). The curve 43 depicts the energy calculated by VQE.

As described earlier, when the distance is small, both CCSD(T) and VQE have sufficient accuracy. However, when the distance is large, although VQE has relatively high accuracy, the accuracy of CCSD(T) greatly falls. The molecules for which FCI may be executed are limited to small-scale molecules. The execution time of VQE is also longer than CCSD(T). In view of the characteristics of FCI, CCSD(T), and VQE described above, the information processing apparatus 100 automatically switches between FCI, CCSD(T), and VQE as follows.

First, the information processing apparatus 100 determines, from the viewpoint of hardware resources, whether FCI is executable on the molecule to be simulated. When sufficient hardware resources for executing FCI are available, the information processing apparatus 100 calculates the energy corresponding to all distances by using FCI. On the other hand, when sufficient hardware resources for executing FCI are not available, the information processing apparatus 100 calculates energy by selectively switching between CCSD(T) and VQE depending on the distance.

As one example, the information processing apparatus 100 estimates the memory usage of FCI based on the molecular information and the ground-state function that have been designated. The estimated memory usage is given by “Nstrings2×Narrays×B”. Here, “Nstrings” is the total number of different electron configurations, which is NorbCNelect. Here, “Norb” is the number of molecular orbitals and “Nelect” is the number of electrons. Accordingly, “Nstrings” is the number of combinations for selecting a number of molecular orbitals equal to the number of electrons from the set of all molecular orbitals. This number of electrons is specified from the designated molecule type. The number of molecular orbitals is determined from the designated ground-state function. “Narrays” is the number of arrays used for FCI, for example, 33. “B” is the number of bytes used to express one floating-point value, as one example, 8 bytes.

The information processing apparatus 100 compares the estimated memory usage with the current available memory capacity. The available memory capacity is the size of the RAM area that may be used for FCI, as one example, the current available memory capacity which is obtained from the operating system. The information processing apparatus 100 determines that FCI is executable when the estimated memory usage does not exceed the available memory capacity. On the other hand, the information processing apparatus 100 determines that FCI is not executable when the estimated memory usage exceeds the available memory capacity.

When it has been determined that FCI is not executable, the information processing apparatus 100 calculates the energy in ascending order of distance. The information processing apparatus 100 executes CCSD(T) while the distance is small, and switches the algorithm from CCSD(T) to VQE when the distance becomes large. When doing so, the distance at which the accuracy of CCSD(T) begins to deteriorate varies depending on the molecule to be simulated. For this reason, the information processing apparatus 100 monitors the execution result of CCSD(T) at the most recent distance, and dynamically decides based on this execution result whether to keep the algorithm for the next distance unchanged at CCSD(T) or to change the algorithm to VQE.

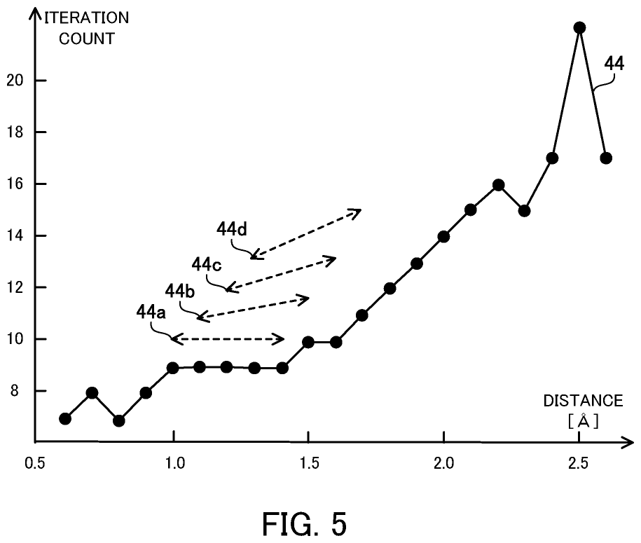

FIG. 5 is a graph depicting an example relationship between distance and iteration count.

A curve 44 depicts the relationship between interatomic distance and the iteration count of CCSD(T). As described earlier, there are tendencies whereby the larger the distance, the lower the accuracy of a CCSD(T) solution, and the lower the accuracy of the solution, the larger the iteration count of CCSD(T). Accordingly, as indicated by the curve 44, the larger the distance, the larger the iteration count of CCSD(T). When the accuracy of the solution of CCSD(T) starts to deteriorate, the iteration count of CCSD(T) increases significantly.

For this reason, when CCSD(T) outputs energy, the information processing apparatus 100 measures and records the iteration count of CCSD(T). The information processing apparatus 100 monitors the iteration count at the most recent distance, and on detecting that the iteration count has increased significantly, determines that the accuracy of the solution of CCSD(T) has started to deteriorate and therefore switches the algorithm.

As one example, the information processing apparatus 100 fits a line segment using the least squares method on a certain number of most recent distances and iteration counts (as one example, the five most recent distances and iteration counts) to calculate the slope of the line segment. The information processing apparatus 100 records the calculated slope. The information processing apparatus 100 determines whether the most recent slope is greater than the slope calculated at the immediately previous distance. When the slope has increased a certain number of times in succession (for example, when the slope has increased three times in succession), the information processing apparatus 100 switches the algorithm to VQE starting from the next distance.

A line segment 44a indicates the slope of the section from 1.0 Å to 1.4 Å, and is obtained when CCSD(T) calculates the energy for the distance of 1.4 Å. A line segment 44b indicates the slope of the section from 1.1 Å to 1.5 Å, and is obtained when CCSD(T) calculates the energy for the distance of 1.5 Å. The slope of the line segment 44b is greater than the slope of the line segment 44a. A line segment 44c indicates the slope of the section from 1.2 Å to 1.6 Å, and is obtained when CCSD(T) calculates the energy for the distance of 1.6 Å. The slope of the line segment 44c is greater than the slope of the line segment 44b. A line segment 44d indicates the slope of the section from 1.3 Å to 1.7 Å, and is obtained when CCSD(T) calculates the energy of the distance of 1.7 Å. The slope of the line segment 44d is greater than the slope of the line segment 44c.

The information processing apparatus 100 detects from the line segments 44a, 44b, 44c, and 44d that the slope has increased three times in succession. As a result, the information processing apparatus 100 calculates the energy of each distance from the distance of 1.8 Å onward using VQE instead of CCSD(T).

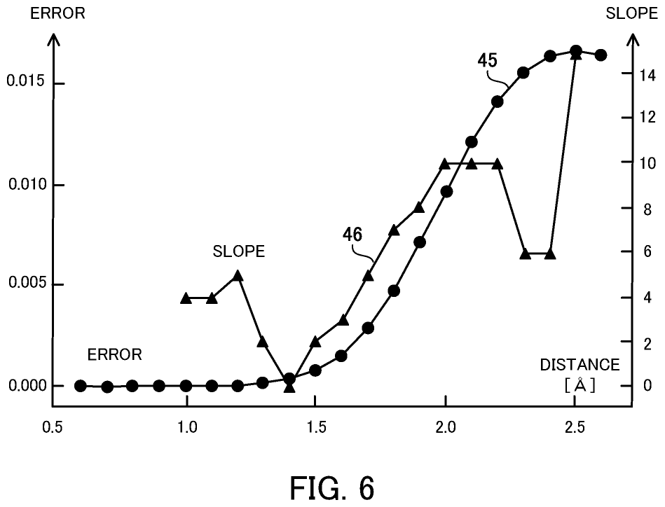

FIG. 6 is a graph depicting an example relationship between distance, error, and slope.

A curve 45 depicts the absolute value of the error of the energy calculated by CCSD(T) with respect to the energy calculated by FCI. As indicated by the curve 45, the error with CCSD(T) increases sharply from the distance of 1.5 Å toward the distance of 2.0 Å. A curve 46 depicts the slope of the five most recent iterations. As indicated by the curve 46, the slope of the iteration count of CCSD(T) increases from the distance of 1.5 Å toward the distance of 2.0 Å. Accordingly, by monitoring the slope of the iteration count, the information processing apparatus 100 is able to detect that the error has started to increase significantly.

Next, the functions and processing procedure of the information processing apparatus 100 will be described.

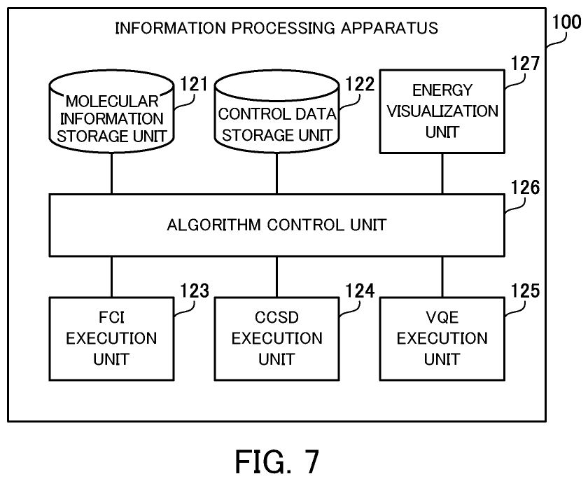

FIG. 7 is a block diagram depicting example functions of the information processing apparatus.

The information processing apparatus 100 includes a molecular information storage unit 121, a control data storage unit 122, an FCI execution unit 123, a CCSD execution unit 124, a VQE execution unit 125, an algorithm control unit 126, and an energy visualization unit 127. The molecular information storage unit 121 and the control data storage unit 122 are implemented using the RAM 102 or the HDD 103, for example. The FCI execution unit 123, the CCSD execution unit 124, the VQE execution unit 125, the algorithm control unit 126, and the energy visualization unit 127 are implemented using the CPU 101 and programs, for example. Note that some or all of the FCI execution unit 123, the CCSD execution unit 124, and the VQE execution unit 125 may be assigned to another information processing apparatus.

The molecular information storage unit 121 stores molecular information. The molecular information includes types and positional coordinates of atoms included in a molecule to be simulated. The molecular information storage unit 121 also stores the ground-state function designated by the user. The ground-state function is usually selected by the user from a group of known ground-state functions according to the type of molecule and the purpose of the molecular simulation. The control data storage unit 122 stores the energy calculated for each of a plurality of distances. The control data storage unit 122 also stores control data used to select an algorithm.

In accordance with an instruction from the algorithm control unit 126, the FCI execution unit 123 executes FCI based on the molecular information and ground-state function that have been designated. The designated molecular information reflects changes in the distance between two specified atoms. The FCI execution unit 123 calculates the ground-state energy for each piece of molecular information corresponding to one distance and outputs the ground-state energy to the algorithm control unit 126.

In accordance with an instruction from the algorithm control unit 126, the CCSD execution unit 124 executes CCSD(T) based on the designated molecular information and ground-state function. However, the CCSD execution unit 124 may execute CCSD instead. The CCSD execution unit 124 calculates the ground-state energy for each piece of molecular information corresponding to one distance and outputs the ground-state energy to the algorithm control unit 126. The CCSD execution unit 124 also measures the iteration count and notifies the algorithm control unit 126 of the iteration count.

In accordance with an instruction from the algorithm control unit 126, the VQE execution unit 125 executes VQE based on the designated molecular information and ground-state function. The VQE execution unit 125 repeatedly generates a quantum circuit and measures the energy based on the molecular information and the ground-state function. The VQE execution unit 125 calculates the ground-state energy for each piece of molecular information corresponding to one distance and outputs the ground-state energy to the algorithm control unit 126.

The algorithm control unit 126 selects an algorithm to be used for the quantum chemical calculation separately for each of a plurality of distances. The set of distances for which energy is calculated may be designated by the user or may be fixed in advance. The algorithm control unit 126 estimates the memory usage of FCI based on the molecular information and the ground-state function, and determines whether FCI is executable based on the estimated memory usage and the available memory capacity. When FCI is executable, the algorithm control unit 126 calls the FCI execution unit 123 for every distance.

When FCI is not executable, the algorithm control unit 126 calls the CCSD execution unit 124 in ascending order of distance. The algorithm control unit 126 monitors the slope of the iteration count measured by the CCSD execution unit 124 and calls the VQE execution unit 125 for all remaining distances when the slope has increased for a certain number of times in succession. The algorithm control unit 126 also stores the energies corresponding to all of the distances collected from the FCI execution unit 123, the CCSD execution unit 124, and the VQE execution unit 125 in the control data storage unit 122.

The energy visualization unit 127 reads the plurality of energies corresponding to a plurality of distances from the control data storage unit 122 and plots the read energies to generate a potential energy curve. The energy visualization unit 127 may store the generated potential energy curve in non-volatile storage, display the potential energy curve on the display apparatus 111, and/or transmit the potential energy curve to another information processing apparatus. Also, the energy visualization unit 127 may output numerical data itself indicating the plurality of energies that have been calculated.

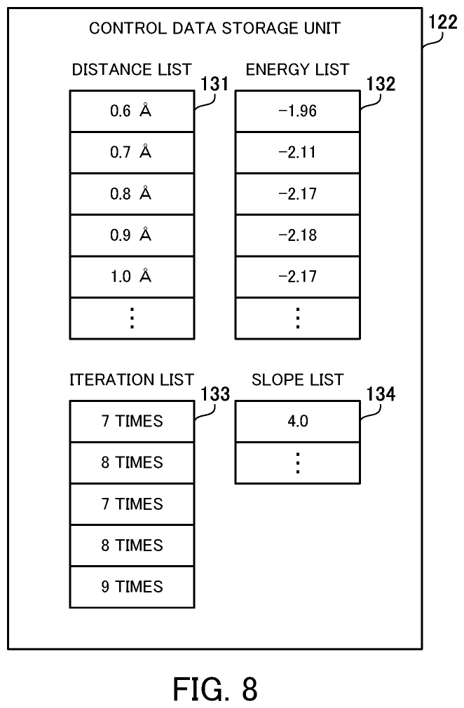

FIG. 8 is a diagram depicting an example structure of the control data.

The control data storage unit 122 stores a distance list 131, an energy list 132, an iteration list 133, and a slope list 134. The distance list 131 is a list of distances whose energies have not yet been calculated. The energy list 132 is a list in which the calculated energies are listed in ascending order of distance. The iteration list 133 is a list in which the iteration counts of CCSD(T) are listed for a fixed number of most recent distances. The iteration counts are listed in ascending order of distance. The slope list 134 is a list in which the slopes of iteration counts calculated from the iteration list 133 are listed in ascending order of distance.

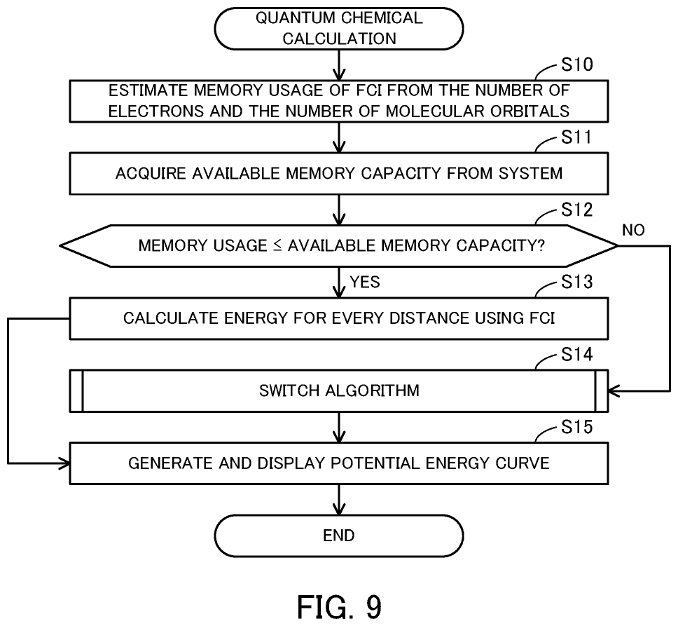

FIG. 9 is a flowchart depicting an example procedure of a quantum chemical calculation.

(S10) The algorithm control unit 126 specifies the number of electrons from the molecular information and specifies the number of molecular orbitals from the ground-state function. The algorithm control unit 126 estimates the memory usage of FCI by inputting the number of electrons and the number of molecular orbitals into an estimation formula.

(S11) The algorithm control unit 126 acquires the memory capacity in the system that is available for a quantum chemical calculation. The system may be the information processing apparatus 100 or may be another information processing apparatus. The available memory capacity is obtained from the operating system, for example.

(S12) The algorithm control unit 126 determines whether the memory usage estimated in step S10 is equal to or less than the available memory capacity acquired in step S11. When the memory usage is equal to or less than the available memory capacity, the processing proceeds to step S13. When the memory usage exceeds the available memory capacity, the processing proceeds to step S14.

(S13) The FCI execution unit 123 calculates the energy for every distance by FCI. The algorithm control unit 126 records the calculated energies in the energy list 132 in ascending order of distance. The processing then proceeds to step S15.

(S14) The algorithm control unit 126 executes algorithm switching that switches between CCSD(T) and VQE. This algorithm switching will be described in detail later.

(S15) The energy visualization unit 127 reads the energies recorded in the energy list 132 in step S13 or step S14, and plots the read energies to generate a potential energy curve. The energy visualization unit 127 displays the generated potential energy curve on the display apparatus 111.

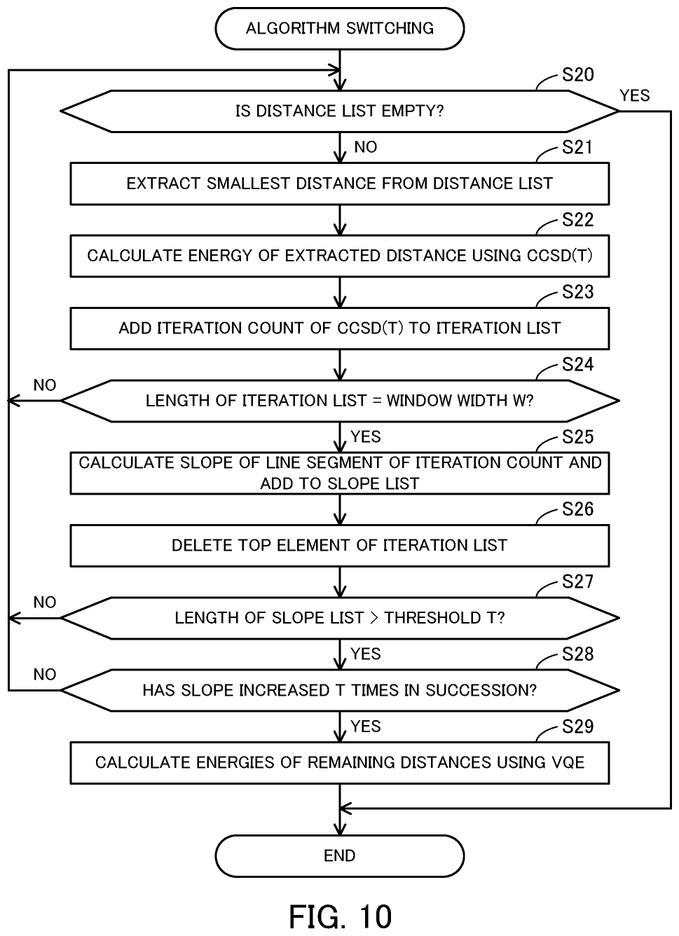

FIG. 10 is a flowchart depicting an example procedure for algorithm switching.

Algorithm switching is executed in step S14 described above.

(S20) The algorithm control unit 126 determines whether the distance list 131 is empty. In an initial state, distances for which energy is to be calculated are listed in ascending order in the distance list 131. When the distance list is empty, algorithm switching ends. When the distance list is not empty, the processing proceeds to step S21.

(S21) The algorithm control unit 126 extracts what is currently the shortest distance from the top of the distance list 131. This extracted distance is then deleted from the distance list 131.

(S22) The CCSD execution unit 124 calculates the energy corresponding to the distance extracted in step S21 by CCSD(T). The CCSD execution unit 124 also measures the iteration count, that is, the number of iterations for the energy to converge.

(S23) The algorithm control unit 126 adds the energy calculated in step S22 to the end of the energy list 132. The algorithm control unit 126 also adds the iteration count measured in step S22 to the end of the iteration list 133.

(S24) The algorithm control unit 126 determines whether the length of the iteration list 133 is equal to a certain window width W. As one example, W=5. When the length of the iteration list 133 is equal to the window width W, the processing proceeds to step S25. When the length of the iteration list 133 is smaller than the window width W, the processing returns to step S20.

(S25) The algorithm control unit 126 fits a line segment to W iteration counts included in the iteration list 133 using the least-squares method. The algorithm control unit 126 calculates the slope of this line segment and adds the slope to the end of the slope list 134.

(S26) The algorithm control unit 126 deletes one iteration count from the top of the iteration list 133. As a result, the length of the iteration list 133 becomes W−1.

(S27) The algorithm control unit 126 determines whether the length of the slope list 134 exceeds a threshold T. As one example, T=3. When the length of the slope list 134 exceeds the threshold T, the processing proceeds to step S28. When the length of the slope list 134 is equal to or less than the threshold T, the processing returns to step S20.

(S28) The algorithm control unit 126 scans the T+1 slopes at the end of the slope list 134 and determines whether the slope has increased T times in succession. When the slope has increased T times in succession, the processing proceeds to step S29. When this is not the case, the processing returns to step S20.

(S29) The VQE execution unit 125 calculates energies corresponding to all remaining distances included in the distance list 131 using VQE. The algorithm control unit 126 adds the calculated energies to the end of the energy list 132. The algorithm control unit 126 empties the distance list 131. The algorithm switching then ends.

Next, another method for selecting distances for which VQE is to be executed will be described.

First, the information processing apparatus 100 executes CCSD(T) for each of a plurality of distances for which energy is to be found. However, the information processing apparatus 100 may execute another classical algorithm that involves a small amount of calculation, such as CCSD, in place of CCSD(T). Next, based on the iteration counts of CCSD(T) for the plurality of distances, the information processing apparatus 100 then selects distances for which VQE is additionally to be executed from the plurality of distances. The information processing apparatus 100 executes VQE for the selected distances. However, it is also possible for the information processing apparatus 100 to select no distances for additionally executing VQE.

When generating the potential energy curve, the information processing apparatus 100 uses the energies calculated by CCSD(T) for distances for which VQE was not executed. On the other hand, from the viewpoint of calculation accuracy, the information processing apparatus 100 uses the energies calculated by VQE for the distances for which VQE has been executed.

To select distances for executing VQE, the information processing apparatus 100 plots points corresponding to distances and iteration counts, and performs piecewise linear regression analysis on the set of plotted points. Piecewise linear regression analysis detects a dividing point and calculates different line segments before and after the dividing point so as to maximize the accuracy of the fit to a set of points.

Here, the information processing apparatus 100 selects a distance to be used as the dividing point, and calculates separate line segments by the least-squares method for the section where the distance is smaller than the dividing point and the section where the distance is larger than the dividing point. The information processing apparatus 100 evaluates residuals indicating the fitting accuracy for the two line segments. The information processing apparatus 100 repeats the regression analysis and evaluation of residuals while changing the dividing point, and searches for the dividing point that maximizes the accuracy of the fit (that is, minimizes the residuals). By doing so, two line segments are calculated with a distance where the tendency of change in the iteration count changes as the boundary.

The information processing apparatus 100 compares the slopes of the two line segments. When the slope of the larger distance section is greater than the slope of the smaller distance section, the information processing apparatus 100 determines that VQE is to be executed on each distance belonging to the larger distance section. In this case, VQE is executed for distances from the dividing point onward. On the other hand, when the slope of the larger distance section is less than or equal to the slope of the smaller distance section, the information processing apparatus 100 determines to not perform VQE for any of the distances. By doing so, the information processing apparatus 100 is able to accurately detect the distance at which the iteration count starts to increase significantly as the distance increases.

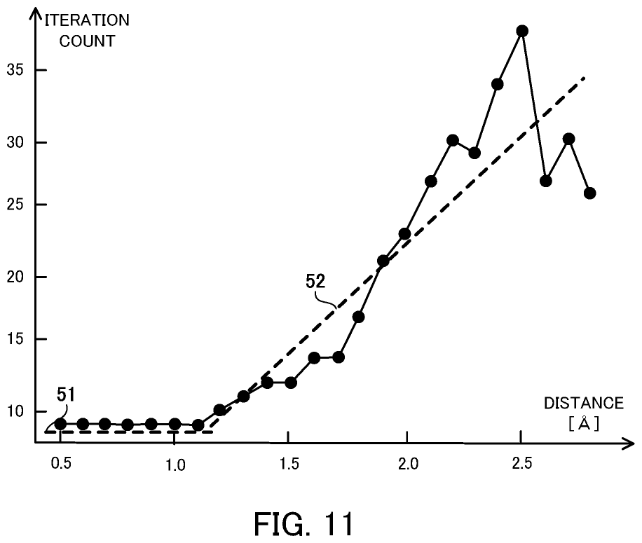

FIG. 11 depicts an example of piecewise linear regression analysis.

In this example, the information processing apparatus 100 executes CCSD(T) for every distance from 0.5 Å to 2.8 Å and measures the iteration counts. The information processing apparatus 100 performs piecewise linear regression analysis on the measured iteration counts to calculate line segments 51 and 52.

The dividing point is between 1.0 Å and 1.1 Å. The section before the dividing point is from 0.5 Å to 1.0 Å. The line segment 51 is calculated from points included in this section. The section after the dividing point is from 1.1 Å to 2.8 Å. The line segment 52 is calculated from points included in this section. As depicted in FIG. 11, the tendency of how the iteration count fluctuates clearly differs before and after the dividing point. The slope of the line segment 52 is greater than the slope of the line segment 51. For this reason, the information processing apparatus 100 additionally executes VQE for each distance from 1.1 Å to 2.8 Å corresponding to the line segment 52.

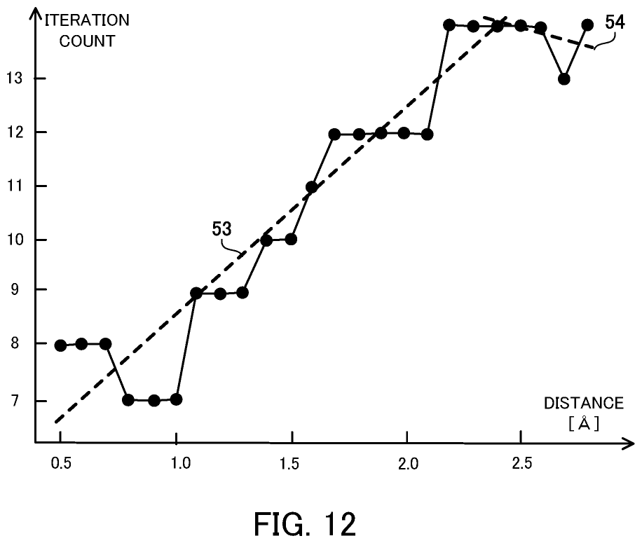

FIG. 12 depicts another example of piecewise linear regression analysis.

In this example, the information processing apparatus 100 executes CCSD(T) for each distance from 0.5 Å to 2.8 Å and measures the iteration counts. The information processing apparatus 100 performs piecewise linear regression analysis on the measured iteration counts to calculate line segments 53 and 54.

The dividing point is between 2.4 Å and 2.5 Å. The section before the dividing point is from 0.5 Å to 2.4 Å. The line segment 53 is calculated from points included in this section. The section after the dividing point is from 2.5 Å to 2.8 Å. The line segment 54 is calculated from points included in this section. Unlike the case in FIG. 11, the iteration count tends to increase continuously over the entire range of distances. The line segment 54 has a more gradual slope than the line segment 53. For this reason, the information processing apparatus 100 does not additionally perform VQE for any distance from 0.5 Å to 2.8 Å.

As described above, the information processing apparatus 100 according to the second embodiment generates a potential energy curve indicating the relationship between the interatomic distance and the ground-state energy of a molecule using a quantum chemical calculation. By doing so, the information processing apparatus 100 is capable of providing useful information about the properties of a molecule, and thereby support research and development, such as development of materials or pharmaceuticals. In addition, the information processing apparatus 100 automatically selects which algorithm is to be used to calculate energy for which interatomic distances from the viewpoints of accuracy and execution time. As a result, the user does not need to designate an algorithm for each interatomic distance, which reduces the burden placed on the user. In addition, a highly accurate potential energy curve is generated efficiently in a short time.

The information processing apparatus 100 also estimates the amount of hardware resources used by FCI from the molecular information and the ground-state function, determines whether FCI is executable, and, when FCI is executable, calculates the energy of all interatomic distances using FCI. By doing so, highly accurate potential energy curves are generated for small-scale molecules.

Also, when FCI is not executable, the information processing apparatus 100 calculates the energy for small interatomic distances by CCSD(T) and calculates the energy for large interatomic distances by VQE. By doing so, a favorable balance is achieved between accuracy and execution time. The information processing apparatus 100 also determines the timing for switching the algorithm from CCSD(T) to VQE based on an increase in the slope of the iteration count until the energy converges for CCSD(T). As a result, any fall in the accuracy of CCSD(T) is detected, and the algorithm is changed at appropriate timing in keeping with the molecule to be simulated.

According to an aspect of the present disclosure, it is possible to efficiently generate energy curve information through a quantum chemical calculation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A non-transitory computer-readable recording medium storing therein a computer program that causes a computer to execute a process comprising:
calculating each of a plurality of first molecular energies corresponding to a plurality of first interatomic distances by using a first algorithm that iteratively updates a solution until a convergence condition is satisfied;
specifying, based on a slope of a line segment indicating a relationship between the plurality of first interatomic distances and iteration counts of the first algorithm until the convergence condition is satisfied, a plurality of second interatomic distances; and
calculating a plurality of second molecular energies corresponding to the plurality of second interatomic distances by using a second algorithm which differs from the first algorithm.

2. The non-transitory computer-readable recording medium according to claim 1, wherein
the specifying of the plurality of second interatomic distances is based on whether the slope exceeds a threshold.

3. The non-transitory computer-readable recording medium according to claim 1, wherein the process further includes:
generating a potential energy curve based on the calculated plurality of first molecular energies and the calculated plurality of second molecular energies.

4. The non-transitory computer-readable recording medium according to claim 1, wherein
a plurality of interatomic distances for which molecular energy is to be calculated are stored, and
the plurality of second interatomic distances are interatomic distances, out of the plurality of interatomic distances, that are larger than any first interatomic distance out of the plurality of first interatomic distances.

5. The non-transitory computer-readable recording medium according to claim 1, wherein
the specifying of the plurality of second interatomic distances is based on whether the slope exceeds a threshold, the plurality of first molecular energies are calculated in ascending order of the plurality of first interatomic distances, and
the threshold is a slope of a line segment obtained immediately before a most recent first interatomic distance or a slope of a line segment of a section for a smaller interatomic distance out of line segments of two sections obtained from the iteration counts of the plurality of first interatomic distances.

6. The non-transitory computer-readable recording medium according to claim 1, wherein
the second algorithm has a longer execution time than the first algorithm and a higher solution accuracy than the first algorithm.

7. The non-transitory computer-readable recording medium according to claim 1, wherein
the first algorithm is coupled cluster singles and doubles (and triples) (CCSD(T), and the second algorithm is variational quantum eigensolver.

8. The non-transitory computer-readable recording medium according to claim 1, wherein
the process further includes:
determining whether a third algorithm, which differs from the first algorithm and the second algorithm, is usable or not based on molecular information indicating a target molecule and available memory capacity, and
the first algorithm is used in place of the third algorithm when the third algorithm is determined to be unusable.

9. The non-transitory computer-readable recording medium according to claim 8, wherein
the determining includes estimating memory usage based on at least one of a number of electrons and a number of molecular orbitals of the target molecule and determining that the third algorithm is unusable when the memory usage that has been estimated exceeds the available memory capacity.

10. The non-transitory computer-readable recording medium according to claim 8, wherein
the third algorithm has a longer execution time than the second algorithm and a higher solution accuracy than the second algorithm.

11. The non-transitory computer-readable recording medium according to claim 8, wherein
the third algorithm is full configuration interaction (FCI).

12. An algorithm selecting method comprising:
calculating, by a processor, each of a plurality of first molecular energies corresponding to a plurality of first interatomic distances by using a first algorithm that iteratively updates a solution until a convergence condition is satisfied;
specifying, by the processor and based on a slope of a line segment indicating a relationship between the plurality of first interatomic distances and iteration counts of the first algorithm until the convergence condition is satisfied, a plurality of second interatomic distances; and
calculating, by the processor, a plurality of second molecular energies corresponding to the plurality of second interatomic distances by using a second algorithm which differs from the first algorithm.

13. An information processing apparatus comprising:
a memory configured to store iteration counts of a first algorithm until a convergence condition is satisfied when a plurality of first molecular energies corresponding to a plurality of first interatomic distances have been calculated by using the first algorithm that iteratively updates a solution until the convergence condition is satisfied; and
a processor coupled to the memory and the processor configured to:
specify, based on a slope of a line segment indicating a relationship between the plurality of first interatomic distances and the iteration counts, a plurality of second interatomic distances; and
calculate a plurality of second molecular energies corresponding to the plurality of second interatomic distances by using a second algorithm which differs from the first algorithm.
